(19) United States
(12) Patent Application Publication
(10) Pub. No.: US 2014/0034363 A1
(43) Pub. Date: Feb. 6, 2014

(54) MULTI-LAYER TRANSMISSION LINES

(71) Applicant: Samtec, Inc., New Albany, IN (US)

(72) Inventor: Gary Ellsworth BIDDLE, Carlisle, PA (US)

(73) Assignee: SAMTEC, INC., New Albany, IN (US)

(21) Appl. No.: 13/957,089

(22) Filed: Aug. 1, 2013

Related U.S. Application Data
(63) Continuation of application No. 13/957,017, filed on Aug. 1, 2013.
(60) Provisional application No. 61/678,614, filed on Aug. 1, 2012.

(51) Int. Cl. H05K 1/02

(52) U.S. Cl. CPC H05K 1/0216
USPC 174/254; 174/268; 174/262

(57) ABSTRACT

A substrate including a first transmission line arranged to transmit electrical signals and including first and second traces and a first dielectric layer. The first and second traces are separated from each other by the first dielectric layer. A printed circuit board includes a first transmission line arranged to transmit electrical signals and including first, second, and third traces; and a first dielectric layer. The first and second traces are separated from the third trace by the first dielectric layer.

### BACKGROUND OF THE INVENTION

1. Field of the Invention

The present invention relates to transmission lines, which are sometimes referred to as waveguides. More specifically, the present invention relates to multi-layer transmission lines on a printed circuit board (PCB).

2. Description of the Related Art

Current connector development is driven by increasingly faster data rates in smaller spaces. Transmission lines provided on a PCB are required to be smaller and smaller, thus requiring tighter and tighter manufacturing tolerances. As the space between adjacent transmission lines decreases, more crosstalk isolation between adjacent transmission lines is needed. The requirement of greater signal density also applies to the electrical connector of the interconnect.

Consider a PCB array interconnect in which a PCB is connected to an electrical connector on at least one end. The electrical connector includes an array of contacts that make contact with contact pads on the PCB so that signals can be transmitted through the PCB and the electrical connector. Smaller contact pitch in the electrical connector requires that less PCB space for the contact pads be used for the transmission lines on the PCB. With less PCB space for the transmission lines, the challenge is to maintain isolation between adjacent transmission lines, while having to deal with tighter manufacturing tolerances to control geometry and to maintain impedance integrity. Both the propagation through the PCB and the transition from the PCB to the electrical connector affect the transmitted signals.

FIGS. 1-3 show a pair of transmission lines 101, 102 on a PCB 100. Each transmission line 101, 102 includes a pair of coupled microstrips 101a, 101b and 102a, 102b for transmitting a differential signal, where the pair of coupled microstrips 101a, 101b and 102a, 102b are coupled to each other. To provide acceptable crosstalk isolation between adjacent transmission lines 101, 102, the accepted industry practice is to use a thin dielectric layer 103 to establish a strong electromagnetic field coupling between the groundplane 104, which is the bottom layer in FIGS. 2 and 3, and the pair of coupled microstrips 101a, 101b and 102a, 102b. The middle ground structure including groundplane 105 between the transmission lines and with a via picket fence made of vias 106 is also required for acceptable crosstalk isolation.

As microstrip widths and dielectric layer thicknesses decrease, tighter manufacturing tolerances are required to meet the impedance requirements. Currently, PCB manufacturers can provide widths/traces down to 0.002″/0.002″ to 0.003″/0.003″ accuracy with tolerances of ±20%. Incorrect impedance characteristics are the biggest reason that PCBs are found to be unacceptable during manufacturing. The geometries of high-speed data transmission channels are being specified to achieve a tighter impedance tolerance of ±5%; however, PCB manufacturers would prefer ±10% impedance tolerances to allow for fewer defects. PCBs with impedances outside the impedance tolerances must be scrapped, which adds to the fabrication costs of the PCBs.

In the geometry of FIGS. 1-3, the close proximity of the groundplane 104 directly under the pair of coupled microstrips 101a, 101b and 102a, 102b confines the electromagnetic fields of the differential signal transmitted through the pair of coupled microstrips 101a, 101b and 102a, 102b and the groundplane 104. This is a disadvantage for the differential signal transmission from the PCB 100 to the electrical connector (not shown) because of an impedance mismatch caused by the different geometries of the PCB 100 and the electrical connector. The prior art differential coplanar traces 201a, 201b and 202a, 202b discussed next attempts to address this issue.

FIGS. 4-6 show a pair of transmission lines 201, 202 on PCB 200. Each transmission line 201, 202 includes a pair of traces 201a, 201b and 202a, 202b for transmitting a differential signal, where the pair of traces 201a, 201b and 202a, 202b are coupled to each other as a coplanar differential pair. The top view of the coplanar differential pairs of FIG. 4 is similar to the top view of the coupled microstrip differential pairs of FIG. 1; however, with coplanar differential pairs, the traces 201a, 201b and 202a, 202b are wider than the coupled microstrips 101a, 101b and 102a, 102b, and the pair of traces 201a, 201b and 202a, 202b has a smaller spacing between them than the spacing between the pair of coupled microstrips 101a, 101b and 102a, 102b. In addition, with coplanar differential pairs, there is no groundplane on the bottom layer. With coplanar differential pairs, the electromagnetic fields are confined to the location around the pair of traces and are not coupled to a lower groundplane.

As seen in FIGS. 5 and 6, coplanar differential pairs only require one copper layer (i.e., the layer defined by traces 201a, 201b and 202a, 202b, for signal transmission. The similarities between the geometries of the coplanar differential pair in the PCB 200 and in the electrical connector (not shown) allows for easier impedance matching. The impedance is easier to match because the electromagnetic fields of the coplanar differential pair in the PCB 200 and the electrical connector are similar and do not have to change much in the transitions between the PCB 200 and the electrical connector compared to the transition between the PCB 100 and the electrical connector for the coupled microstrip differential pairs.

A problem with using coplanar differential pairs arises when the width of the traces 201a, 201b and 202a, 202b are reduced. The spacing between the pair of traces 201a, 201b and 202a, 202b can be reduced to meet impedance targets; however, the required spacing cannot be manufactured. In addition, reducing the width of the pair of traces 201a, 201b increases the resistances of the pair of traces 201a, 201b, which results in higher temperatures and in higher losses.

As shown in FIG. 6, the characteristic impedance Zo of the known coplanar structure depends on distances s1, s2, s3 and widths t1, t2. To achieve greater signal density, the widths t1, t2 must be decreased so that the coplanar structure resides in less physical space, which in turn requires that the distances s1, s2, s3 be decreased to maintain the desired characteristic impedance Zo. The distances s1, s2, s3 and widths t1, t2 can quickly become impossible to manufacture with accuracy.

### SUMMARY OF THE INVENTION

To overcome the problems described above, preferred embodiments of the present invention provide a PCB for an interconnect that has greater signal density, that can be actually manufactured, and that has improved performance in that the PCB provides improved high-speed signal integrity and the ability to provide low-level contact resistance (LLCR), i.e., low-level path resistance for DC signals or low-frequency AC signals.

A printed circuit board according to a preferred embodiment of the present invention includes a first transmission line arranged to transmit electrical signals and including first, second, and third traces; and a first dielectric layer. The first and second traces are separated from the third trace by the first dielectric layer.

The first transmission line preferably transmits differential signals. The printed circuit board preferably further includes a second transmission line arranged to transmit electrical signals and including fourth, fifth, and sixth traces; and a second dielectric layer. The fourth and fifth traces are preferably separated from the sixth trace by the second dielectric layer. Preferably, the first and second transmission lines preferably are on a same side of the printed circuit board so that the second dielectric layer is the first dielectric layer, or the first and second transmission lines are on opposite sides of the printed circuit board so that the first and second dielectric layers are different.

The printed circuit board preferably further includes a second dielectric layer adjacent to the third trace but separate from the first dielectric layer. The first and second dielectric layers are preferably made from different materials.

The printed circuit board preferably further includes a groundplane coplanar with the first and second traces. The printed circuit board preferably further includes a groundplane coplanar with the third trace. The printed circuit board preferably further includes a first groundplane coplanar with the first and second traces and a second groundplane coplanar with the third trace.

An assembly according to a preferred embodiment of the present invention includes a printed circuit board according to a preferred embodiment of the present invention and an electrical connector including first and second contacts that are connected to the first and second traces.

The assembly preferably further includes a target printed circuit board to which the electrical connector is connected. The electrical connector preferably further includes third and fourth contacts that are on opposite sides of the first and second contacts and that are connected to a groundplane on the printed circuit board.

A substrate according to a preferred embodiment of the present invention includes a first transmission line arranged to transmit electrical signals and including first and second traces; and a first dielectric layer. The first and second traces are separated from each other by the first dielectric layer.

The substrate preferably is a printed circuit board, a rigid printed circuit board, or a flexible printed circuit board. The substrate preferably is a semiconductive material.

The substrate preferably further includes a second dielectric layer adjacent to the second trace but separate from the first dielectric layer. The first and second dielectric layers are preferably made from different materials.

The substrate preferably further includes a groundplane coplanar with the first trace. The substrate preferably further includes a groundplane coplanar with the second trace. The substrate preferably further includes a first groundplane coplanar with the first trace and a second groundplane coplanar with the second trace.

The first and second traces are preferably connected by vias. The first transmission line preferably transmits single-ended signals. The first transmission line preferably further includes third and fourth traces that are separated from each other by the first dielectric layer. The third and fourth traces are preferably connected by vias. The first transmission line preferably transmits differential signals.

The transmission line preferably includes a third trace that is coplanar with the first trace such that the first and third traces are separated from the second trace by the first dielectric layer. The first transmission line preferably transmits differential signals.

An assembly according to a preferred embodiment of the present invention includes a substrate according a preferred embodiment of the present invention and an electrical connector including a first contact that is connected to the first trace. The assembly preferably further includes a target printed circuit board to which the electrical connector is connected. The substrate preferably is either a rigid printed circuit board or a flexible printed circuit board.

An assembly according to a preferred embodiment of the present invention includes a substrate according to a preferred embodiment of the present invention and a cable connected to the first trace. The cable is preferably an optical cable.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 is top plan view of conventional coupled microstrip differential pairs.

FIG. 2 is a cross-sectional view of the coupled microstrip differential pairs shown in FIG. 1.

FIG. 3 is a close-up cross-sectional view of the coupled microstrip differential pairs shown in FIG. 1.

FIG. 4 is top plan view of conventional co-planar differential pairs.

FIG. 5 is a cross-sectional view of the co-planar differential pairs shown in FIG. 4.

FIG. 6 is a close-up cross-sectional view of the co-planar differential pairs shown in FIG. 4.

FIG. 7 is top plan view of a differential pair of transmission lines according to a first preferred embodiment of the present invention.

FIG. 8 is a cross-sectional view of the differential pair of transmission lines shown in FIG. 7.

FIG. 9 is a close-up cross-sectional view of the differential pair of transmission lines shown in FIG. 7.

FIG. 10 is a close-up cross-sectional view of a differential pair of transmission lines according to the first preferred embodiment of the present invention with groundplanes.

FIG. 11 is a top perspective view of a PCB according to the first preferred embodiment of the present invention.

FIG. 12 is a graph showing the differential insertion loss and the differential return loss versus frequency.

FIG. 13 shows the internal groundplanes of a PCB according to the first preferred embodiment of the present invention.

FIG. 14 is a cross-sectional view a differential pair of transmission lines according to a second preferred embodiment of the present invention.

FIG. 15 is a cross-sectional view a differential pair of transmission lines according to a second preferred embodiment of the present invention with groundplanes.

FIG. 16 is a top perspective view of the differential pair of transmission lines shown in FIG. 15.

FIG. 17 is a cross-sectional view of the differential pair of transmission lines shown in FIG. 15.

FIG. 18 is a top perspective view of a single-ended transmission line according to a second preferred embodiment of the present invention.

FIG. 19 is a cross-sectional view of the single-ended transmission line shown in FIG. 18.

FIG. 20 is close-up top perspective view the single-ended transmission line shown in FIG. 18.

FIG. 21 is a graph showing the differential insertion loss and the differential return loss versus frequency.

FIG. 22 is a top perspective view of a PCB according to the first preferred embodiment of the present invention.

### DETAILED DESCRIPTION OF PREFERRED EMBODIMENTS

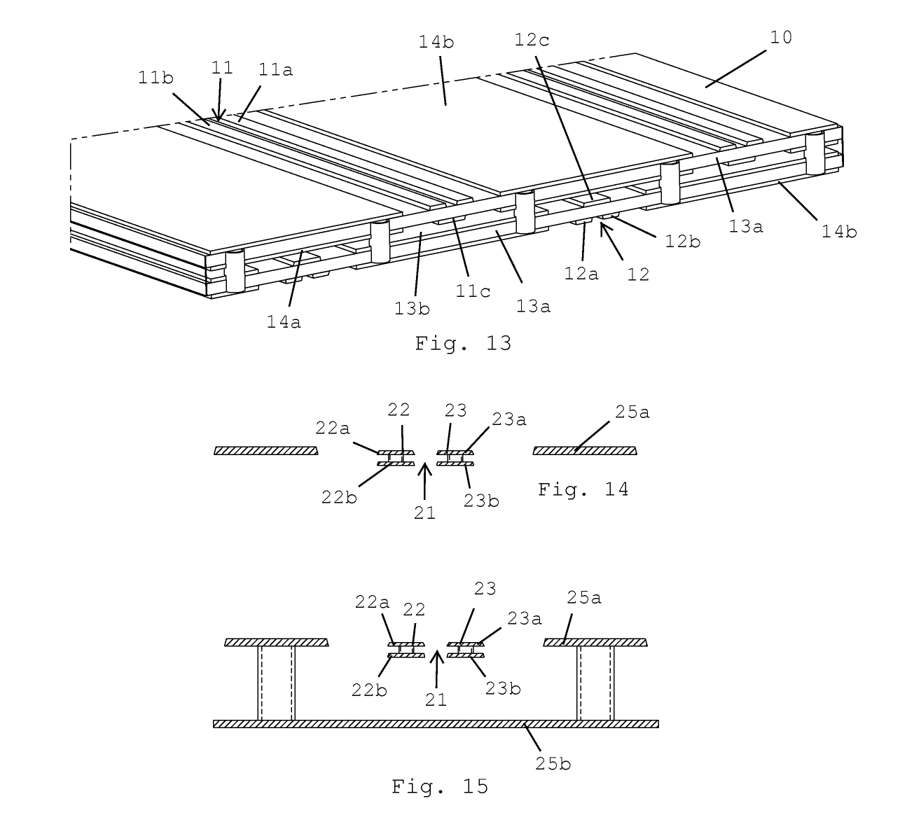

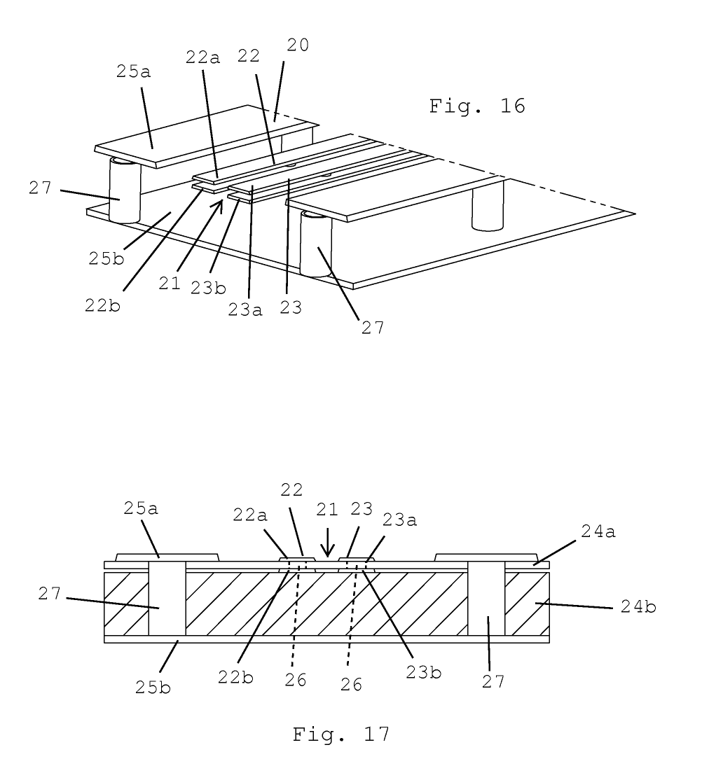

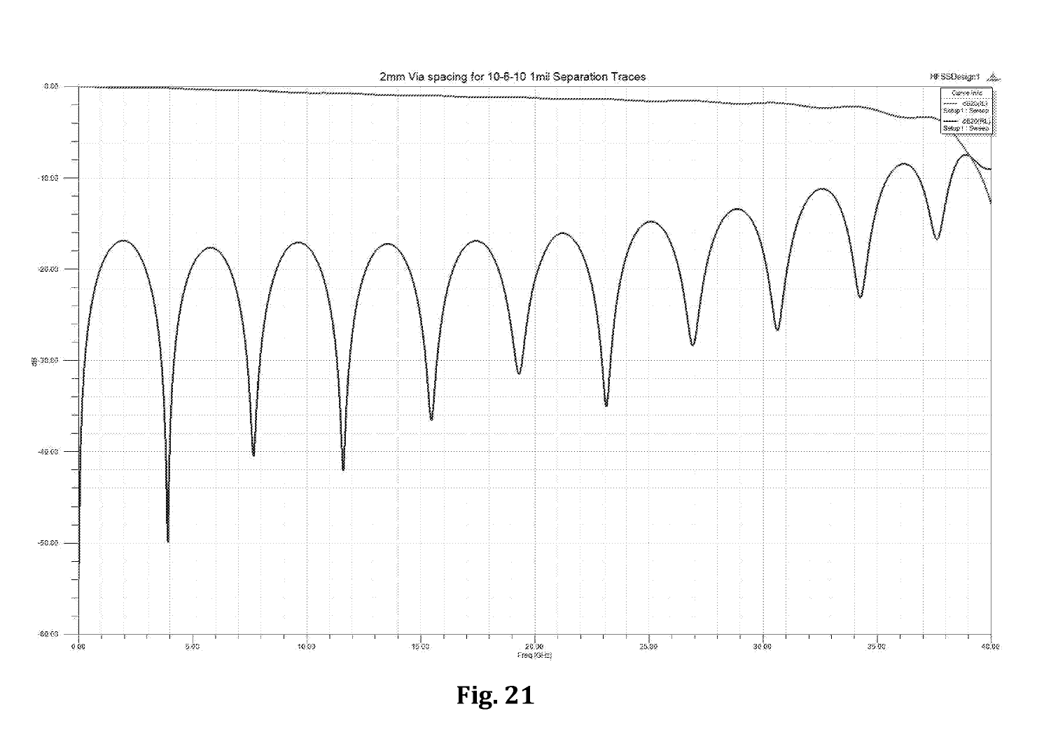

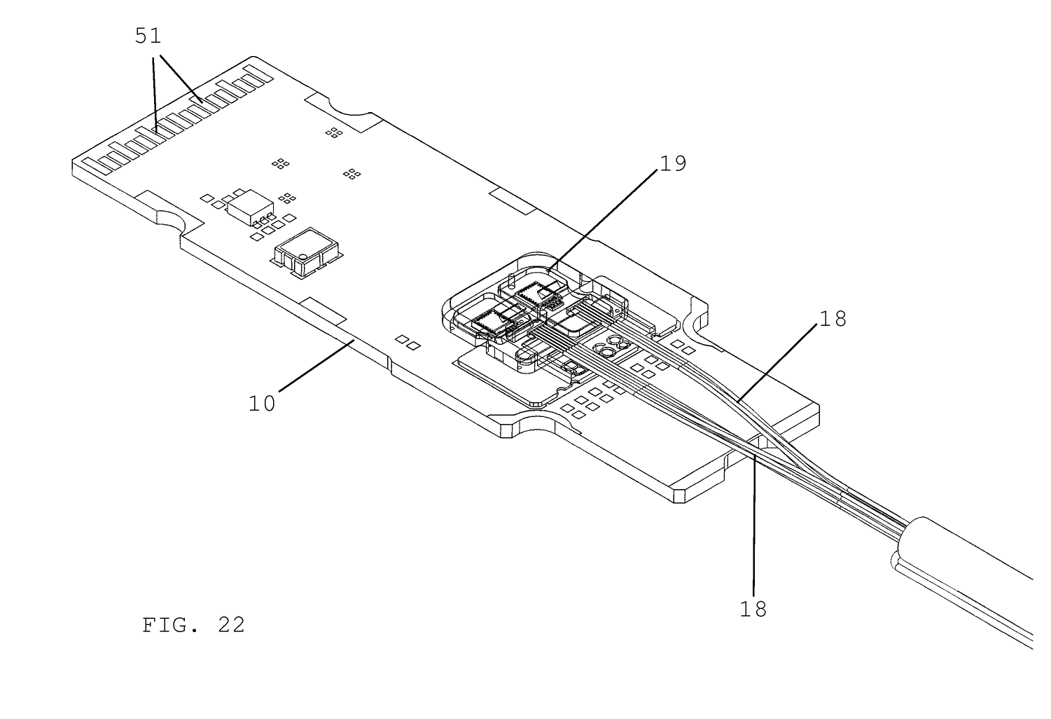

Preferred embodiments of the present invention are shown in FIGS. 7-21. FIGS. 7-13 show the first preferred embodiment of the present invention, and FIGS. 14-21 show the second preferred embodiment of the present invention.

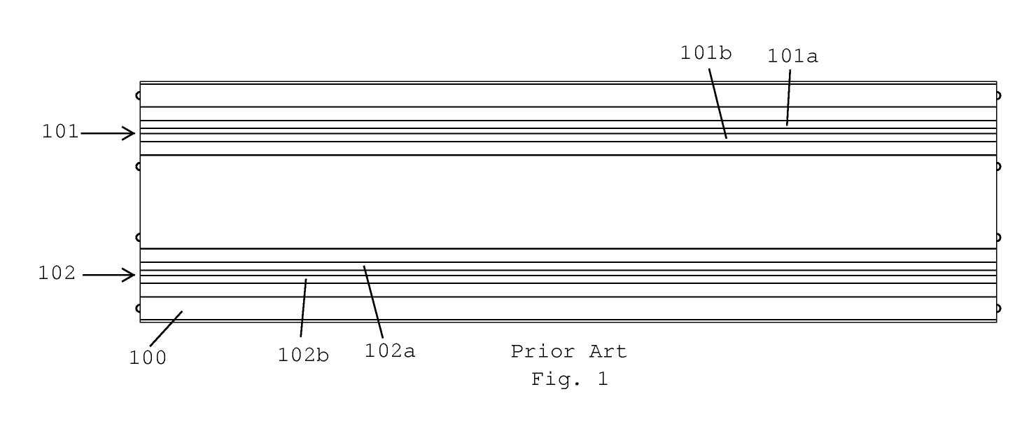

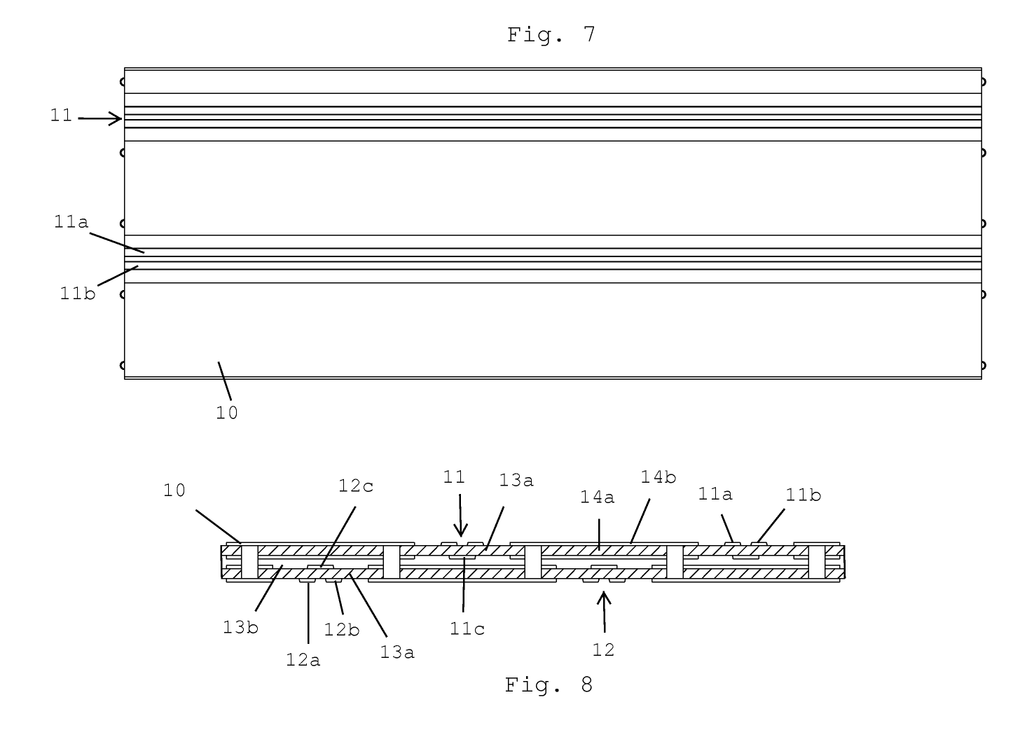

FIGS. 7-9 shows transmission lines 11, 12 on both sides of PCB 10, with transmission line 11 on the top of the PCB 10 in the orientation shown in FIG. 8 and with transmission line 12 on the bottom of the PCB 10 in the orientation shown in FIG. 8. Each transmission line 11, 12 includes a pair of traces 11a, 11b and 12a, 12b that transmit a differential signal, where the pair of traces 11a, 11b and 12a, 12b are coupled to each other as a differential pair. The top view of the differential pairs of FIG. 7 is similar to the top view of the microstrip differential pairs of FIG. 1 and the coplanar differential pairs of FIG. 4; however, in the first preferred embodiment, each pair of transmission lines 11, 12 includes a third trace 11c, 12c arranged below, above the pair of traces 11a, 11b and 12a, 12b. The third traces 11c, 12c and the pair of traces 11a, 11b and 12a, 12b are separated by dielectric layer 12a. Another dielectric layer 12b is located below, above the third trace 11c, 12c.

Groundplanes 14a, 14b are located below, above the dielectric layer 12b; are in the same plane as the traces 11a, 11b, 11c, 12a, 12b, 12c; and are separated by the lower, upper dielectric layer 12a. Groundplanes 14a, 14b are not required, but if present do not necessarily have to be arranged in the same plane as the traces 11a, 11b, 11c, 12a, 12b, 12c. If the groundplanes 14a, 14b are arranged in the same plane as the traces 11a, 11b, 11c, 12a, 12b, 12c, then the groundplanes 14a, 14b and the traces 11a, 11b, 11c, 12a, 12b, 12c can be formed at the same time and/or out of the same material.

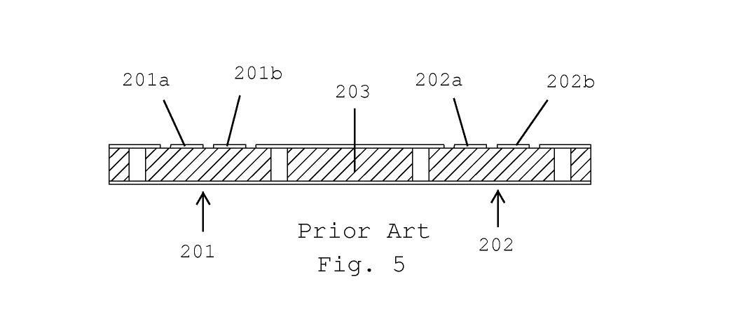

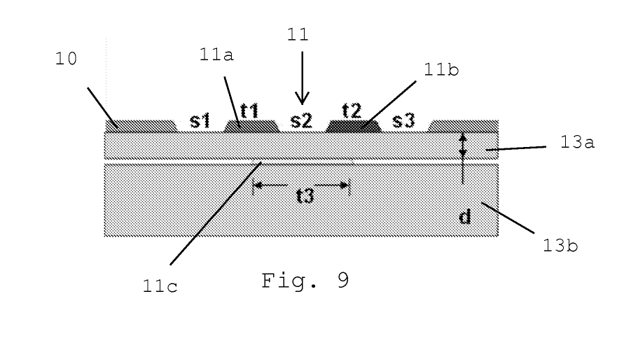

As shown in FIG. 9, the third trace 11c with a thickness t3 is located below the differential pair of traces 11a, 11b with a dielectric layer 13a having of thickness d located between the third trace 11c and the pair of traces 11a, 11b. The characteristic impedance Zo of the structure shown in FIG. 9 depends on the thickness d and width t3. Because of differential cancellation, the overall potential of the third trace 11c is neutral, while maintaining the benefits of the coplanar differential pair configuration shown in FIGS. 4-6 but with increased electromagnetic field intensities between the differential pair of traces 11a, 11b and the third trace 11c. Thus, it is possible to increase the electromagnetic field intensity using larger spacing of distances s1, s2, s3 compared to those used for the coplanar differential pair. The larger spacing can be manufactured while providing improved isolation at more obtainable values of the characteristic impedance Zo.

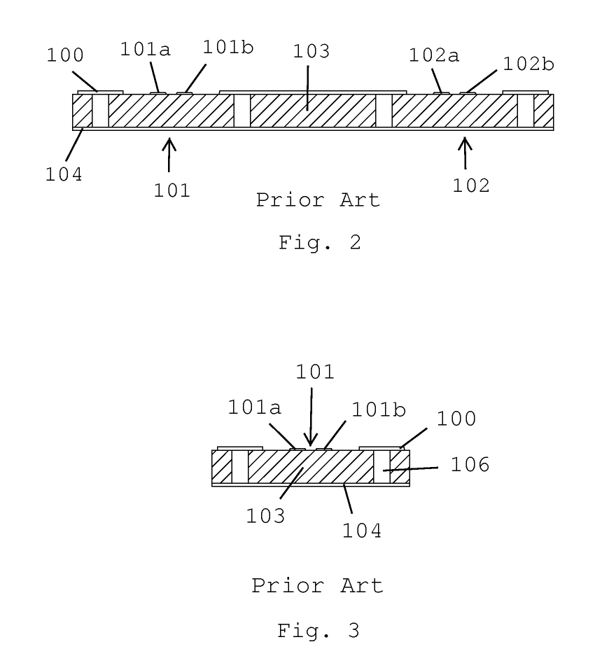

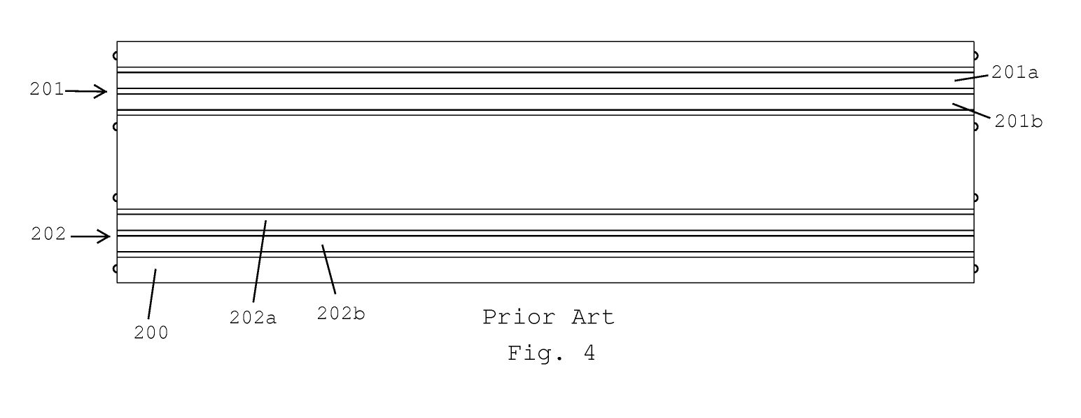

In this preferred embodiment, as a non-limiting example, a differential impedance of 85Ω can be obtained using widths t1, t2, t3 of about 10 mil and thickness d of about 8 mil, which is within the scope of the conventional PCB fabrication process. It is possible to achieve 85Ω with different widths t1, t2, t3, spacings s1, s2, s3, and thickness d, and it is possible to achieve different impedances with different widths t1, t2, t3, spacings s1, s2, s3, and thickness d. In contrast, the conventional coupled microstrip arrangement shown in FIGS. 1-3 would require tighter coupling to the lower ground plane, i.e., thickness d of about 3 mil to 4 mil, which is difficult to manufacture.

The third trace 11c allows the pair of traces 11a, 11b to be reduced in size compared to the coplanar differential pairs and allows the pitch to be reduced, which increases the signal density.

The third trace 11c, not only provides additional options for determining impedance, but also establishes a lower boundary for the electromagnetic fields. The third trace 11c confines a larger portion of the electromagnetic field in the dielectric layer 13a as opposed to the arrangement with no boundary where more of the electromagnetic field penetrates the dielectric layer 13b, which causes a greater loss.

It is possible to use the same or different materials for the dielectric layers 13a, 13b. For example, the dielectric layer 13a could be a more-expensive high-performance signal core, while the dielectric layer 13b could be less-expensive low-performance filler core.

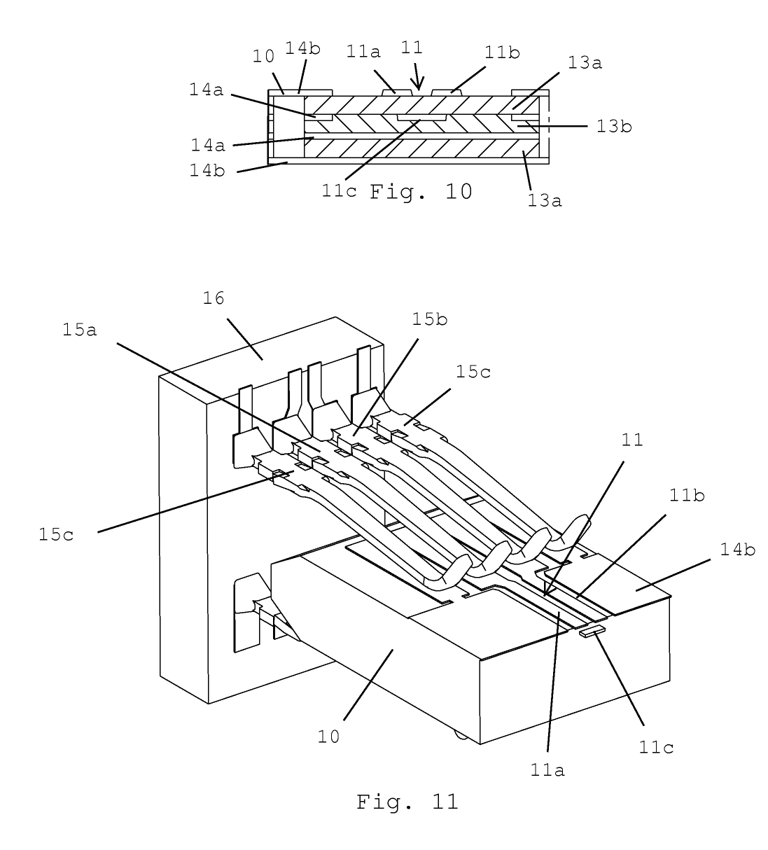

Additionally, the third trace's 11c ability to confine electromagnetic fields within the dotted ellipse of FIG. 10 indicates that the differential signal transmission has better focus and interacts less with the surrounding structures. Less crosstalk means greater isolation between adjacent transmission lines as the signal density is increased.

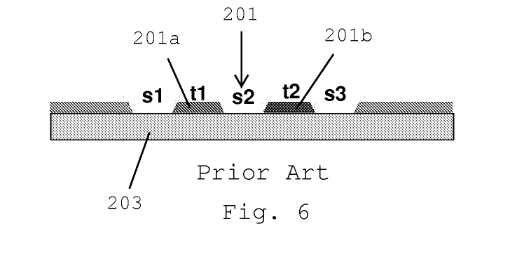

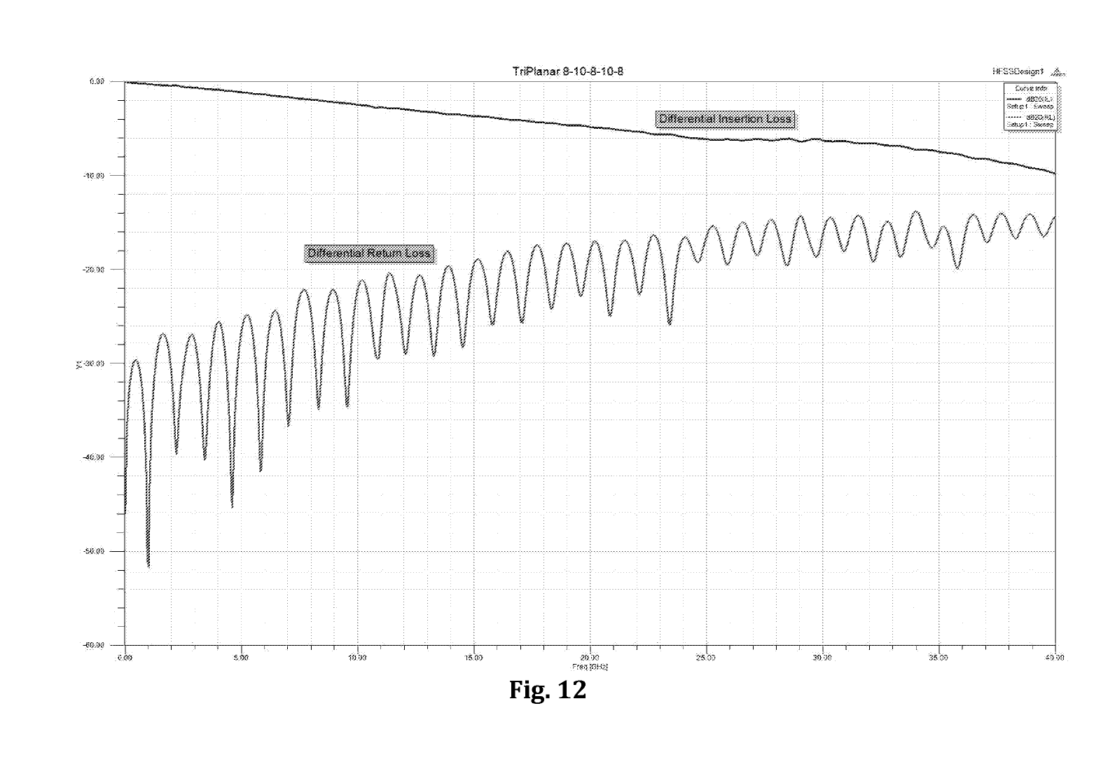

When compared to the coplanar differential pair shown in FIG. 6, the first preferred embodiment of the present invention effectively reduces the cavity height below the differential pair as shown in FIG. 10, which prevents higher-order modes from occurring until much higher frequencies. This effectively extends the operating frequency of the first preferred embodiment of the present invention with regard to loss and crosstalk, as shown in FIG. 12.

FIG. 11 shows one example of an application in which the PCB 20 can be used. FIG. 11 shows PCB 10 connected to contacts 15a, 15b, 15c. 0For simplicity, FIG. 11 does not show the electrical connector that houses the contacts 15a, 15b, 15c. FIG. 11 shows that the contacts 15a, 15b, 15c are connected to a target 17, which typically would be a PCB. The contacts 15a, 15b, 15c are preferably arranged such that contacts 15a, 15b are signal contacts connected to traces 11a, 11b and such that contacts 15c are ground contacts connected to groundplanes 14b. Thus, differential signals can be transmitted through the adjacent signal contacts 15a, 15b. It is an advantage to maintain this ground-signal-signal-ground (G-S-S-G) geometry for the PCB 10 as well. The first preferred embodiment of the present invention matches this G-S-S-G geometry, while the geometry of the microstrip differential pairs with the required groundplane does not because there is no structure within an electrical connector corresponding to the groundplane in the PCB.

In addition to the example application shown in FIG. 11, it is possible to use the PCB 10 in other applications in which a PCB is used to transmit differential signals. For example, the PCB 10 could be used as a part of a cable assembly in which cables are connected to the PCB to transmit differential signals through the PCB or as a part of an optical assembly in which electrical signals are transmitted through the PCB. One such optical assembly is disclosed in U.S. application Ser. No. 13/667,107. FIG. 22 in this application corresponds to FIG. 6 in U.S. application Ser. No. 13/667,107, except that the PCB 10 is used to transmit electrical signals. Optical fibers 18 are connected to the PCB 10, and optical engine 19 is attached to the PCB 10. The optical engine 19 converts electrical signals to optical signals and optical signals to electrical signals. In FIG. 22, the transmission lines 11, 12 are included on an interior surface of the PCB 10, and only the contact pads 51 at the edge of the PCB 10 are on the surface of the PCB.

The addition of a third trace 11c, 12c below, above the pair of differential traces 11a, 11b and 12a, 12b creates a new cross-sectional geometry for differential signal transmission.

The third trace 11c, 12c determines one or more of the following:

1. Impedance Matrix—The third trace 11c, 12c creates a mechanism that increases the capacitive coupling between the pair of differential traces 11a, 11b and 12a, 12b to lower impedance value. The width of the traces 11a, 11b, 11c, 12a, 12b, 12c and the thickness of the dielectric layer 13a between the traces 11a, 11b, 11c, 12a, 12b, 12c are variables that can be adjusted to control the impedance. For example, increased coupling to the third trace 11c, 12c can be used to relax the spacing requirements between the pair of differential traces 11a, 11b and 12a, 12b, thus reducing the spacing error effects on impedance.

2. Electromagnetic Field Focus—The third trace 11c, 12c confines the electromagnetic fields in a smaller cross-sectional area as shown in FIG. 10, which improves isolation between adjacent transmission lines 11, 12 and increases the electromagnetic field focus in the dielectric layer 13a between the traces 11a, 11b, 11c, 12a, 12b, 12c.

The dielectric layer 13a can be selected for thickness and material properties. Most of the electromagnetic field not located in air will be focused in the dielectric layer 13a. This provides the advantage of allowing a high-performance laminate material to be used only for the dielectric layer 13a, which provides cost savings.

The coplanar groundplane 14a can be manufactured from the copper layer used to form the third trace 11, at no additional cost. The presence of the coplanar groundplane 14a tied together by vias 16 will shield and restrict the electromagnetic fields within the PCB 10 as shown in FIG. 13. The internal groundplane 14a reduces crosstalk coupling within the PCB 10 and increases the isolation between transmission lines 11, 12.

The addition of a groundplane 14a within the PCB 10 reduces the transmission line size, which allows for transmission at higher frequencies, as compared to a coplanar differential pair structure of equal thickness.

Coplanar groundplane 14a reduces the overall height of the PCB 10, thus preventing higher-order modes from occurring until much higher frequencies. This removes possible modes of transmission between transmission lines 11, 12 at lower frequencies, which prevents crosstalk in this frequency range.

The third trace 11c, 12c can be connected to adjoining groundplanes through grounding bars or structures. In addition, the third trace 11c, 12c can have different shapes near the edge of the PCB 10 where the pair of differential traces 11a, 11b and 12a, 12b end in contact pads, as seen in FIG. 11, that are arranged for the contacts 15a, 15b, 15c to be engaged with. The shape of the end of the third trace 11c, 12c can be selected to help capacitively compensate for the inductance caused by the beams of the contacts 15a, 15b, 15c. For example, the end of the third trace 11c, 12c can have the same cross-section as the other portions of the third trace all the way to the end of the PCB 10, can have a contact-pad shape of similar to the pair of differential traces 11a, 11b and 12a, 12b, can have an arrow shape with extending structures that do or do not connect to adjoining groundplanes, can end in a point, or can have any other shape. It is also possible that the third trace 11c, 12c ends such that the third trace 11c, 12c does not extend under the contact pads of the pair of differential traces 11a, 11b and 12a, 12b.

This preferred embodiment of the present invention can be applied to a three-layer copper structure to create a best case transition, including differential to differential transition and single-ended to differential transition, with regard to impedance matching. For example, two wide single-ended traces using a first layer for signal traces and a second layer for ground reference could make a transition to a PCB according to this preferred embodiment of the present invention using a first layer for differential signal traces, a second layer for the third trace, and a third layer for ground reference. This would be helpful where miniature differential transmission lines would be attached to single-end test equipment.

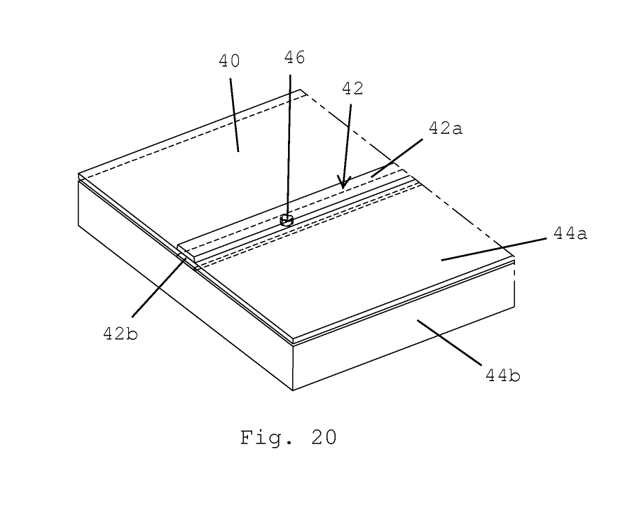

FIGS. 14-19 show dual-layer transmission lines 21, 31 according to the second preferred embodiment of the present invention. FIGS. 14-17 show a differential dual-layer transmission line 21 with dual-layer traces 22, 23 on PCB 20, and FIGS. 18 and 19 show a single-ended dual-layer transmission line 31 with dual-layer trace 32 on PCB 30.

As seen FIGS. 14-17, traces 22, 23 include top traces 22a, 23a on the surface of the PCB 20 and include bottom traces 22b, 23b located on an internal layer of the PCB 20. The pair of traces 22, 23 of the transmission line 21 are arranged to transmit a differential signal, where traces 22a, 22b and 23a, 23b are coupled to each other as a differential pair. The top 22a, 23a and bottom 22b, 23b traces are separated by dielectric layer 24a. Another dielectric layer 24b is located below the bottom traces 22b, 23b.

Groundplane 25a is preferably coplanar with the top traces 22a, 23a, and groundplane 25b is preferably located below the dielectric layer 24b. Groundplanes 25a, 25b are not required. If the groundplane 25a is provided in the same plane as the top traces 22a, 23a, then the groundplane 25a and the top traces 22a, 23a can be formed at the same time and/or out of the same material.

The top traces 22a, 23a and the bottom traces 22b, 23b are connected by vias 26, and the groundplanes 25a, 25b are connected by vias 27. The vias 26 are preferably spaced dependent on the upper frequency limit of signal transmitted through the transmission line 21.

As seen FIGS. 18 and 19, trace 32 includes top trace 32a on the surface of the PCB 30 and includes bottom trace 32b located on an internal layer of the PCB 30. The traces 32 of the transmission line 31 are arranged to transmit a single-ended signal. The top 32a and bottom 32b traces are separated by dielectric layer 34a. Another dielectric layer 34b is located below the bottom trace 32b.

Groundplane 35a is preferably coplanar with the top trace 32a, and groundplane 35b is preferably located below the dielectric layer 34b. Groundplanes 35a, 35b are not required. If the groundplane 35a is provided in the same plane as the top trace 32a, then the groundplane 35a and the top trace 32a can be formed at the same time and/or out of the same material.

The top trace 32a and the bottom trace 32b are connected by vias 36, and the groundplanes 35a, 35b are connected by vias 37. The vias 26 are preferably spaced dependent on the upper frequency limit of signal transmitted through the transmission line 31.

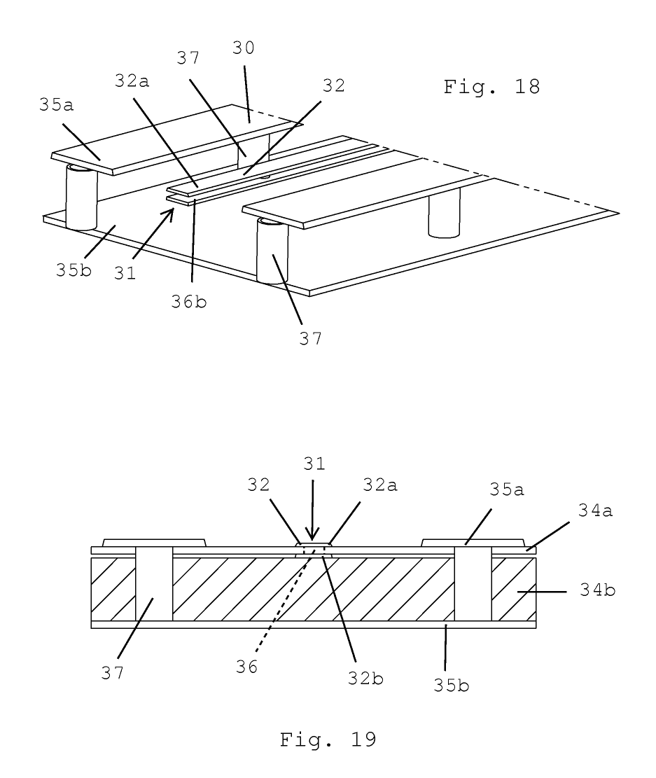

In this preferred embodiment for differential signals and as shown in FIG. 17, the bottom traces 22b, 23b have widths t3, t4 and are separated from the top traces 22a, 23a by dielectric layer 24a with a thickness d. The characteristic impedance Zo depends on the thickness d and widths t1, t2, t3, t4. The addition of bottom traces 22b, 23b increases the electromagnetic field coupling down into the dielectric layer 24a, beyond what upper traces 22a, 23a can do by themselves. The power density in the dielectric layer 24a is increased in space s2 between the dual-layer traces 22, 23 because of the increased coupling between the traces 22a, 22b, 23a, 23b. The increased coupling allows impedance targets to be achieved for spacing s2 having larger widths. Thus, it is possible to increase the electromagnetic field focus for spacings s1, s2, s3 having larger widths to allow possible fabrication while still providing improved isolation at more obtainable values of the characteristic impedance Zo.

Thus, it is possible to effectively double, within the same required space, the equivalent cross-section area of the dual-layer traces 22, 23 compared to single layer traces. The initial coupling isolation remains, with increased power density flow within the PCB 20.

Using dual-layer traces 22, 23 of the second preferred embodiment of the present invention allows:

1. fabrication of lower impedance transmission lines;
2. relaxed tolerances on the spacings s1, s2, s3 and widths t1, t2 shown in FIG. 17;

3. the characteristic impedance Zo to be controlled using widths t3 and t4 trace widths;

4. greater electromagnetic field confinement in the PCB 20 among the traces 22a, 22b, 23a, 23b;

5. tighter field coupling for reduced crosstalk;

6. dielectric layer 24a can be a high-performance signal core that reduces loss;

7. increased frequency range for PCB 20 by adding groundplanes 25b below bottom traces 22b, 23b that push the parallel plate cutoff frequency higher; and

8. higher signal density with 50% lower LLCR because of the approximate doubling in the cross-sectional area of the trace compared to an arrangement with a single layer trace.

In this preferred embodiment for single-ended signals and as shown in FIG. 19, the bottom trace 32b has a width t2 and is separated from the top traces 32a by dielectric layer 34a with a thickness d. The characteristic impedance Zo depends on the thickness d and widths t1, t2. The addition of bottom traces 32b, 23b increases the electromagnetic field coupling down into the dielectric layer 34a, beyond what upper trace 32a can do by itself. The power density in the dielectric layer 34a is increased because of the increased coupling between the traces 32a, 32b. Thus, it is possible to increase the electromagnetic field focus for spacings s1, s2 having larger widths to allow possible fabrication while still providing improved isolation at more obtainable values of the characteristic impedance Zo.

Thus, it is possible to effectively double, within the same required space, the equivalent cross-section area of the dual-layer trace 32 compared to a single layer trace. The initial coupling isolation remains, with increased power density flow within the PCB 30.

Using dual-layer traces 22, 23 of the second preferred embodiment of the present invention allows:

1. fabrication of lower impedance transmission lines;

2. relaxed tolerance on spacings s1, s2 and widths t1 and t2;

3. the characteristic impedance Zo to be controlled using width t2;

4. greater electromagnetic field confinement in the PCB 30 between the upper 32a and lower 32b traces;

5. Tighter field coupling for reduced crosstalk;

6. Dielectric layer 34a 1 can be a high-performance signal core that reduces loss;

7. increased frequency range for PCB 30 by adding groundplane 35a below bottom trace 32b that pushes the parallel plate cutoff frequency higher; and

8. higher signal density with about 50% lower LLCR because of the approximate doubling in the cross-sectional area of the trace compared to an arrangement with a single layer trace.

Using dual layer traces 22, 23, 32 is equivalent to doubling the width of a single layer trace, which leads to the reduction in LLCR, but without degrading the crosstalk between adjacent transmission lines that would accompany doubling the width of a single layer trace.

Although FIGS. 14-19 show dual-layer traces 22, 23, 32 with top 22a, 23a, 32a, and bottom 22b, 23b, 32b traces, it is possible to add one or more layers to the traces 22, 23, 32. For example, it is possible to provide triple-layer traces by adding another trace so that the triple layer trace included top, middle, and bottom traces that are connected by vias.

As with the PCB 10 of the first preferred embodiment, PCBs 20, 30 can be used in any suitable application in which a PCB is used to transmit single-ended or differential signals, including connector-to-connector, PCB-to-cable, and optical applications.

The second preferred embodiment of the present invention can be manufactured shown in FIG. 20 using the following steps. First, provide a PCB 40 with:

1. a thin top trace 42a that is preferably about 0.4 mil to about 0.5 mil thick, for example, and that is made from copper;

2. a dielectric layer 44a that is preferably about 1 mil to about 2 mil thick, for example;

3. a thick bottom trace 42b that is preferably about 1 mil thick and that is made from copper; and

4. a dielectric layer 44b with any suitable thickness.

Then, via holes are formed by laser drilling through the thin top trace 42a and the dielectric layer 44a by using the thick bottom trace 42b as a “stopping base” for a drilling process. Vias 46 are then formed by plating the top trace 42a to a thickness preferably between about 1.4 to about 2.0 mils, for example.

Preferred embodiments of the present invention are directed to the interconnection of PCBs, including PCB array interconnects with PCBs that mate with electrical connectors. It is possible to provide a PCB that uses both the first and second preferred embodiments of the present invention. That is, a single PCB can, for example, include a differential transmission line with a third trace and a differential or single-ended transmission line with dual layer traces.

Preferred embodiments of the present invention can be made using conventional techniques and materials. For example, the traces can be made from copper with platings of lead, tin, silver, gold, gold alloys, an organic conductive coating, or any other suitable material. The dielectric layers are typically made from FR4 but LCP materials, flex, polyamide, or other suitable materials could also be used.

Although the specific examples of the preferred embodiments of the present invention are implemented preferably using PCBs, it should be understood that both rigid and flexible circuit boards could be used. In addition, instead of PCBs, the traces could be formed on any other suitable substrate, including, for example, semiconductor substrates such as silicon dioxide (SiO₂), silicon nitride (SiNO₃), hydrogensilsesquioxanes (HSQ), Teflon-AF (Polytetrafluoethylene or PTFE), silicon oxyflouride (FSG), and nanopourous silica. Of course if semiconductor substrates are used, then the scale will be much smaller. Semiconductor manufacturers can provide widths/traces down to 0.000002″/0.000002″accuracy with tolerances of ±10%. However, the benefits achieved by the preferred embodiments of the present invention when implemented with PCBs can also be achieved when implemented with other substrates including semiconductor substrates.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A substrate comprising:
a first transmission line arranged to transmit electrical signals and including first and second traces; and
a first dielectric layer; wherein the first and second traces are separated from each other by the first dielectric layer.

2. A substrate of claim 1, wherein the substrate is a printed circuit board.

3. A substrate of claim 1, wherein the substrate is either a rigid printed circuit board or a flexible printed circuit board.

4. A substrate of claim 1, wherein the substrate is a semiconductive material.

5. A substrate of claim 1, further comprising a second dielectric layer adjacent to the second trace but separate from the first dielectric layer.

6. A substrate of claim 5, wherein the first and second dielectric layers are made from different materials.

7. A substrate of claim 1, further comprising a groundplane coplanar with the first trace.

8. A substrate of claim 1, further comprising a groundplane coplanar with the second trace.

9. A substrate of claim 1, further comprising a first groundplane coplanar with the first trace and a second groundplane coplanar with the second trace.

10. A substrate of claim 1, wherein the first and second traces are connected by vias.

11. A substrate of claim 10, wherein the first transmission line transmits single-ended signals.

12. A substrate of claim 1, wherein the first transmission line further includes third and fourth traces that are separated from each other by the first dielectric layer.

13. A substrate of claim 12, wherein the third and fourth traces are connected by vias.

14. A substrate of claim 13, wherein the first transmission line transmits differential signals.

15. A substrate of claim 1, wherein the first transmission line includes a third trace that is coplanar with the first trace such that the first and third traces are separated from the second trace by the first dielectric layer.

16. A substrate of claim 15, wherein the first transmission line transmits differential signals.

17. An assembly comprising:
a substrate according to claim 1; and
an electrical connector including a first contact that is connected to the first trace.

18. An assembly of claim 17, further comprising a target printed circuit board to which the electrical connector is connected.

19. An assembly of claim 17, wherein the substrate is either a rigid printed circuit board or a flexible printed circuit board.

20. An assembly comprising:
a substrate according to claim 1; and
a cable connected to the first trace.

21. An assembly of claim 20, wherein the cable is an optical cable.
